(19) United States
(12) Patent Application Publication
(10) Pub. No.: US 2009/0001440 A1
(43) Pub. Date: Jan. 1, 2009

(54) Semiconductor device with buried source rail

(76) Inventors: Max Wei, San Jose, CA (US); Been-Jon Woo, Saratoga, CA (US)

Correspondence Address: TROP PRUNER & HU, PC, 1616 S. VOSS ROAD, SUITE 750, HOUSTON, TX, 77057-2631, US

(21) Appl. No.: 11/821,875

(22) Filed: Jun. 26, 2007

(51) Int. Cl. H01L 29/788; H01L 21/70

(52) U.S. Cl. 257/315; 438/257; 257/E29.3; 257/E21.532

(57) ABSTRACT

In one embodiment of the invention, a NOR Flash memory includes a buried source rail that directly connects to a source strap. Furthermore, a drain plug connects directly to a bit line.

### BACKGROUND

Memory devices such as, for example, a NOR flash memory may contain an array of drain plugs. Each drain plug “stack” may include a metal plug, a metal interconnection, and a metal layer that may be etched to yield a bit line. In other words, the drain plug indirectly connects to the metal layer by way of a metal interconnection. The flash memory may also contain a source rail that may couple to the drain plugs via a floating gate. The source rail may make periodic interconnections to the same metal layer that is used to form bit lines for connecting to the drain plugs. The source rail may indirectly connect to this metal layer by way of a metal interconnect. The metal plug, metal interconnect, and source rail may each be composed of, for example, tungsten. The metal layer may be composed of copper, for example.

### BRIEF DESCRIPTION OF THE DRAWINGS

The accompanying drawings, incorporated in and constituting a part of this specification, illustrate one or more implementations consistent with the principles of the invention and, together with the description of the invention, explain such implementations. The drawings are not necessarily to scale, the emphasis instead being placed upon illustrating the principles of the invention. In the drawings:

FIG. 1a is a side sectional view of a memory device in one embodiment of the invention.

FIG. 1b is a side sectional view of a memory device.

FIG. 2a is a side sectional view of a memory device in one embodiment of the invention.

FIG. 2b is a side sectional view of a memory device.

FIG. 3a is a top sectional view of a memory device in one embodiment of the invention.

FIG. 3b is a top sectional view of a memory device.

### DETAILED DESCRIPTION

The following description refers to the accompanying drawings. Among the various drawings the same reference numbers may be used to identify the same or similar elements. While the following description provides a thorough understanding of the various aspects of the claimed invention by setting forth specific details such as particular structures, architectures, interfaces, and techniques, such details are provided for purposes of explanation and should not be viewed as limiting. Moreover, those of skill in the art will, in light of the present disclosure, appreciate that various aspects of the invention claimed may be practiced in other examples or implementations that depart from these specific details. At certain junctures in the following disclosure descriptions of well known devices, circuits, and methods have been omitted to avoid clouding the description of the present invention with unnecessary detail.

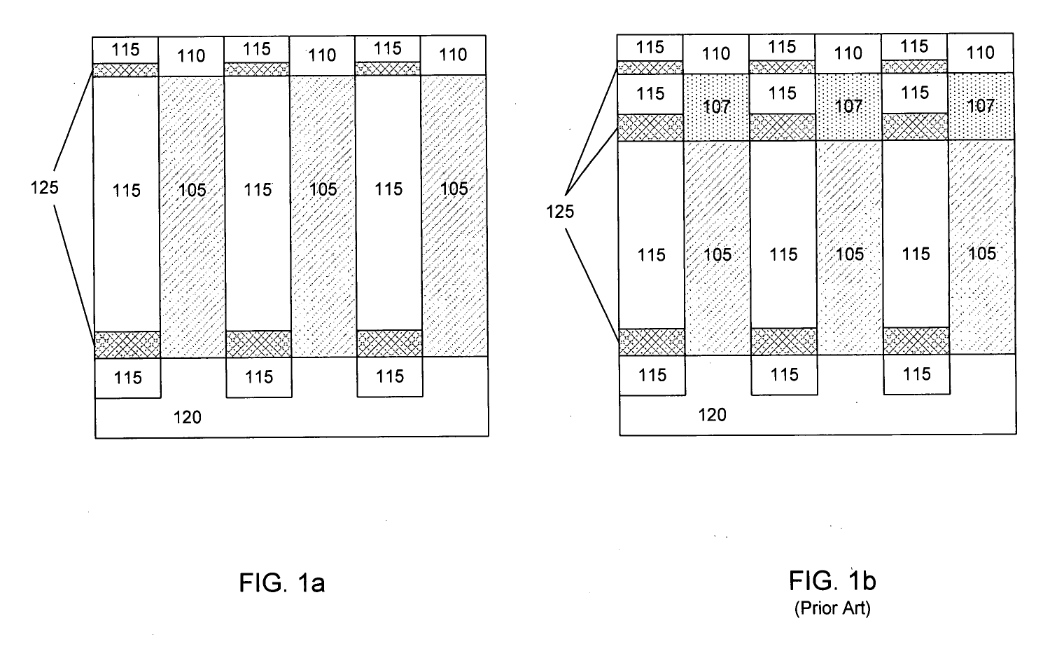

FIG. 1b is a side sectional view of a traditional memory device. Specifically, the figure illustrates an example of a cross section of a traditional NOR flash memory that includes a self-aligned contact architecture. The cross section is taken through a plurality of drain plugs 105. Furthermore, the cross section is made parallel to a word line that is coupled to a floating gate (not shown). Each drain plug 105 may be included in a stack with, from bottom to top, substrate 120, tungsten plug 105 (W1), tungsten interconnect 107 (W2), and a metal layer 110 that may be etched into a bit line. Interspersed between the drain plugs are stacks that may include, from bottom to top, substrate 120, oxide 115, nitride 125, oxide 115, nitride 125, oxide 115, nitride 125, and oxide 115. Thus, the drain plug 105 is indirectly connected to the bit line 110 by way of metal interconnect 107.

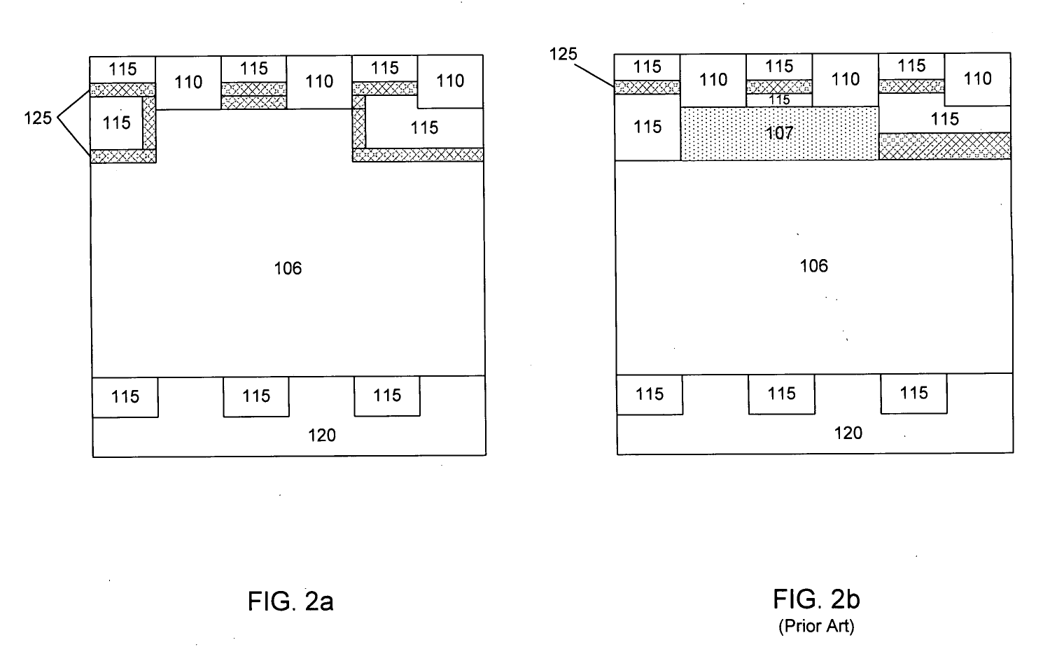

FIG. 2b is a side sectional view of a memory device in the prior art. Specifically, the figure illustrates an example of a cross section of the traditional NOR flash memory of FIG. 1b. The cross section, however, is taken through the source rail 106. Furthermore, the cross section is made parallel to the aforementioned word line and to the cross section of FIG. 1b. Source rail 106 is formed atop substrate 120. Source rail 106 indirectly connects to metal layer (M1), which may be etched to form metal interconnect 110, by way of tungsten interconnect 107 (W2). FIG. 2b further includes a second stack that, from bottom to top, includes substrate 120, isolation oxide 115, source rail 106, nitride 125, oxide 115, nitride 125, oxide 115.

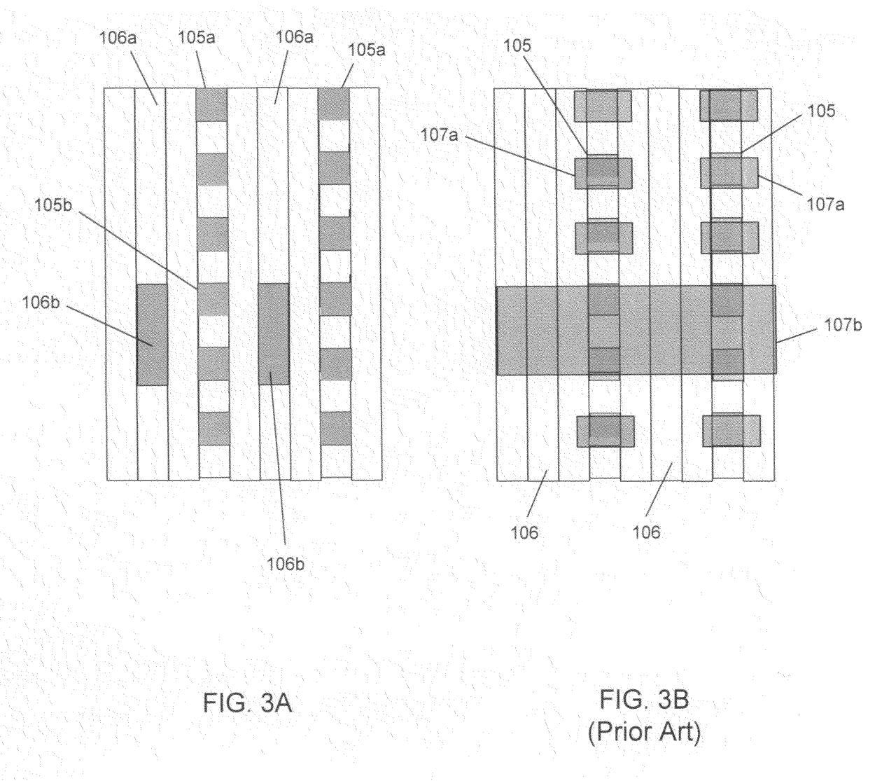

FIG. 3b is a top sectional view of a traditional memory device. This is a top view without M1 metal lines added. Source drains 105 are covered with the second tungsten layer W2 107a. Nonburied source rails 106 interface a second tungsten layer W2 source strap 107b. M1 metal lines may be added horizontally to interface the drain plugs 107a W2 layer and source strap 107b. If the M1 metal lines were to be added directly to the drain plugs 105 or source rail 106 without the intermediary W2 layer, the source and drains may short.

The memory or memories of FIGS. 1b, 2b, and 3b may be fabricated using traditional techniques. Briefly, after forming a self-aligned contact NOR Flash memory array with polished W1 layer, nitride 125, oxide 115, and nitride 125 capping layers are deposited and polished using traditional techniques. A second tungsten layer 107 (W2) may also be formed by lithography and etching to form via holes, then a second tungsten layer 107 deposition and polishing. The W2 pattern 107 serves as a “Via 0” layer and forms a contact with drain plugs 105 and the source rails 106. The M1 layer is then formed to couple the drain plugs 105 and the source rails 106. The M1 layer is subjected to lithography and etching to form bit lines 110 (FIG. 1b) for the drain plugs 105 and interconnects 110 (FIG. 2b) for the source rail 106. In one embodiment of the invention, the M1 layer is copper that is polished.

Thus, the technology of FIGS. 1b, 2b, and 3b may use tungsten W1 for drain plugs 105 and the source rail 106. Critical lithography and etch methods may be used to form vias 107 from tungsten W2. The W2 vias 107 are polished and then critical lithography and etching are performed for the M1 layer. The copper M1 layer may then be polished using traditional techniques.

In contrast to the traditional memories of FIGS. 1b, 2b, and 3b, FIGS. 1a, 2a, and 3a are views of a memory device in one embodiment of the invention. In general, the figures disclose a buried tungsten source rail in a self-aligned contact (SAC) architecture for a NOR-flash memory. More specifically, FIG. 1a illustrates an example of a cross section of a NOR flash memory that may include a self-aligned contact architecture. The cross section is taken through a plurality of drain plugs 105. Furthermore, the cross section is made parallel to a word line that couples to an array of floating gates (not shown). Each floating gate may be coupled to a drain plug 105. Each floating gate, together with an individual drain plug and shared source rail, forms a memory cell. FIG. 2a illustrates an example of a cross section of the NOR flash memory of FIG. 1a. The cross section, however, is taken through the source rail 106. FIG. 3a illustrates an example of a top cross section of the NOR flash memory of FIG. 1a.

FIG. 2a illustrates one embodiment of the invention wherein a buried tungsten source rail 106 is directly connected to a (M1) metallization layer 110. In this embodiment of the invention, there is no interconnecting tungsten via (W2) between the source rail 106 and M1 layer 110. Thus, the W2 deposition and polish operations, described above in regards to traditional NOR flash memory architectures, are unnecessary. This omission of steps may result in lower manufacturing costs. The W1 drain plugs 105 (FIG. 1a) and nonburied portion of the W1 source rails 106 (FIG. 2a) may be polished to the level of the capping nitride layer (not shown) on top of the gate lines.

FIG. 3a is a top sectional view of a memory device in one embodiment of the invention. This is a top view without M1 metal lines added. Drain plugs 105a need not be covered with a second tungsten layer. Source rails 106a, 106b also need not interface a second tungsten layer. Instead, M1 metal lines may be added horizontally to directly interface the drain plugs 105a and nonburied portion of the source rail 106b. No short occurs because the M1 metal lines for the drain plugs 105a only interface oxide or some other insulating material that is placed over the buried portions of the source rail 106a. M1 metal lines that interface the nonburied source rail 106b may interface “dummy” drain plugs 105b that are not addressable.

In one embodiment of the invention, a tungsten (W1) layer 105 (FIG. 1a), 106 (FIG. 2a) is deposited on a substrate 120 and polished. Nitride 125 is deposited. The tungsten source rail 106 is patterned and recess etched to form buried source rail portions as well as non-buried source rail portions. The patterning is such that the drain plugs 105 are covered by resist and hence not recessed. In one embodiment of the invention, a portion of the source rail 106b (FIG. 3a) equivalent to the width of 2-4 W1 drain plugs 105 is covered by resist and hence not recessed. This non-buried portion of the source rail 106b will subsequently form a direct connection to the source strapping layer at M1 110.

In one embodiment of the invention, the source strapping frequency may define, partially or completely, the length of the exposed portion of the pattern that covers part of the source rail 106a (FIG. 3a). This open gap may be, in one embodiment of the invention, the length of 128 memory cells (not shown). In other embodiments of the invention, the gap is the length of 256 memory cells (not shown).

After the W1 recess etch, nitride 125 and oxide 115 may be deposited using traditional techniques. In one embodiment of the invention, oxide 115 may be polished to stop at the nitride layer.

Additional nitride 125 and oxide 115 layers may be patterned and etched to form a M1 metal layer. In one embodiment of the invention, the metal is copper which may be polished to form bit lines 110 (FIG. 1a) for the drain plugs 105 and interconnects or source strap 110 (FIG. 2a) for the non-buried portion of the source rail 106b (FIG. 3a).

For the W1 source rail etch, there is a reasonable selectivity of the cap nitride material to the W etch chemistry. Cap nitride may be the top cladding material on the wordlines. In one embodiment of the invention, there is minimal nitride cap loss with over approximately 700 A tungsten source rail recess, even with a non-optimized etch recipe and with a high degree of incoming cap nitride rounding. Both the incoming cap nitride profile and the W etch recipe may be optimized to improve the resultant selectivity and to reduce the amount of corner rounding.

As an additional point regarding the above processes, the self-aligned contact architecture may be implemented in one embodiment of the invention as follows. A location of a contact opening may be defined using photolithographic techniques. When properly aligned, the contact opening may be centered between polysilicon gate electrodes. In a dry etch process, a contact opening may be formed using etch chemistries having a higher degree of selectivity to nitride than to doped oxide. In this manner, a heavily doped borophosphosilicate glass layer may be removed from the contact opening more rapidly than nitride spacers. As a result, the lower portion of the contact opening may be effectively self-aligned to the space between nitride spacers. Etch chemistries based on CHF₃, CF₄, N₂, and Ar combinations may be used, however the particular etch chemistry employed depends on the type of doping and dopant concentration in the dielectric films to be etched. In addition, the contact opening etch process may comprise multiple steps using multiple etch chemistries. Therefore, even if the location of a contact opening is slightly misaligned during the photolithographic step, spacers may prevent polysilicon gate electrodes from being exposed within the contact opening. The width at the bottom of the contact opening may be modulated by adjusting the thickness of a nitride layer, thereby adjusting the width of spacers as described above.

Thus, in one embodiment of the invention, FIGS. 1a, 2a, and 3a illustrate one embodiment of an inventive flash NOR memory that may include a substrate 120, multiple drain plugs 105, and a source rail 106 that includes a buried portion or portions and a non-buried portion or portions. The buried portion or portions may be located directly beneath an insulating material 125. An array of floating gates may couple the source rail 106 to the drain plugs 105. Multiple bitlines 110, a form of interconnect, are also included. One of the bitlines 110 may be directly connected to one of the drain plugs 105 and to an insulating material 115. Another of the bit lines may be directly connected to another drain plug 105 and to a nonburied portion of the source rail 106. Yet another bitline 110 may be directly connected to another drain plug 105 and to the nonburied portion of the source rail 106. Furthermore, still another bitline 110 may be directly connected to another drain plug 105 and to another insulating material 115. Where the bitlines/interconnects 110 directly contact the source rail 106 and a drain plug 105, the drain plug 105 may be a “dummy plug” that is not addressable and, for example, is connected to ground.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A flash memory comprising:
a substrate;
a first drain plug, a second drain plug, a third drain plug, a fourth drain plug;
a source rail including a first buried portion, a second buried portion, and a first nonburied portion, the first buried portion located directly beneath a first insulating material and the second buried portion located directly beneath a second insulating material;
a first floating gate to couple the source rail to the first drain plug and a second floating gate to couple the source rail to the fourth drain plug; and
a first bitline, a second bitline, a third bitline, a fourth bitline;
wherein the first bitline is directly connected to the first drain plug and the first insulating material, the second bit line is directly connected to the second drain plug and to the first nonburied portion of the source rail, the third bitline is directly connected to the third drain plug and to the first nonburied portion of the source rail, and the fourth bitline is directly connected to the fourth drain plug and to the second insulating material.

2. The flash memory of claim 1, wherein the second drain plug and the third drain plug are each formed between the first drain plug and the fourth drain plug.

3. The flash memory of claim 1, wherein the first drain plug is addressable, the second drain plug is not addressable, the third drain plug is not addressable, and the fourth drain plug is addressable.

4. The flash memory of claim 1, wherein the flash memory is a NOR memory.

5. The flash memory of claim 4, wherein the flash memory includes a self-aligned contact architecture.

6. The flash memory of claim 1, further comprising:
a fifth drain plug, a sixth drain plug, a seventh drain plug, an eighth drain plug;
a third buried portion of the source rail and a second nonburied portion of the source rail, the third buried portion being located directly beneath a third insulating material;
a fifth bitline, a sixth bitline, a seventh bitline, an eighth bitline; and
wherein the fifth bitline is directly connected to the fifth drain plug and the second insulating material, the sixth bit line is directly connected to the sixth drain plug and to the second nonburied portion of the source rail, the seventh bitline is directly connected to seventh drain plug and to the second nonburied portion of the source rail, and the eighth bitline is directly connected to the eighth drain plug and to the third insulating material.

7. The flash memory of claim 6, wherein the first nonburied portion and the second nonburied portion are separated by a first distance, the first distance based on a source strapping frequency.

8. The flash memory of claim 6, wherein the first nonburied portion and the second nonburied portion are separated by a least 100 memory cells and further wherein no additional nonburied portions are located between the first nonburied portion and the second nonburied portion.

9. The flash memory of claim 1, wherein the first insulating material and the second insulating material each include an oxide material.

10. The flash memory of claim 1, wherein a top surface of the first nonburied portion is formed at the same level as a top surface of the first drain plug.

11. A method for forming a memory comprising:
coupling a first drain plug to a substrate;
coupling a source rail to the substrate;
coupling a first gate to the first drain plug;
etching a first portion of the source rail to form a first etched portion and a first unetched portion, the first unetched portion having a top surface at the same level as a top surface of the first drain plug;
coupling a first insulation material to the first etched portion to form a first buried portion of the source rail;
directly connecting a first bitline to the first drain plug; and
directly connecting a second bitline to the first unetched portion.

12. The method of claim 11, further comprising:
coupling a second drain plug to the substrate;
coupling a second gate to the second drain plug;
etching a second portion of the source rail to form a second etched portion and a second unetched portion, the second unetched portion having a top surface at the same level as the top surface of the first drain plug;
directly coupling a third bitline to the second drain plug; and
directly coupling a fourth bitline to the second unetched portion.

13. The method of claim 12, further comprising separating the first unetched portion and the second unetched portion by a first distance based on a source strapping frequency.

14. The method of claim 13, further comprising forming at least 100 memory cells and no additional unetched portions between the first unetched portion and the second unetched portion.

15. The method of claim 11, wherein the first memory is a flash NOR memory that includes a self-aligned contact architecture.
